(19) United States
(12) Patent Application Publication
(10) Pub. No.: US 2025/0275319 A1
(43) Pub. Date: Aug. 28, 2025

(54) DISPLAY PANEL

(71) Applicants: Asphetek Solution9Chengdu) Ltd., Chengdu (CN); ADVANCED OPTOELECTRONIC TECHNOLOGY, INC., Hsinchu County (TW); Asphetek Solution Inc., Hsinchu (TW)

(72) Inventors: SHIUE-LUNG CHEN, Hsinchu (TW); CHANG-HO CHEN, Hsinchu (TW); CHUNG-WU LIU, Hsinchu (TW); I-MING CHENG, Hsinchu (TW)

(21) Appl. No.: 18/646,638

(22) Filed: Apr. 25, 2024

(30) Foreign Application Priority Data
Feb. 28, 2024 (CN) 202410223018.1

(51) Int. Cl. H01L 33/62; H01L 25/075

(52) U.S. Cl. CPC H10H 20/857; H01L 25/0756; H01L 25/0753

(57) ABSTRACT

A display panel includes a substrate and a plurality of pixels on the substrate. Each of the plurality of pixels includes a plurality of sub-pixels coaxially stacked. Each of the plurality of sub-pixels includes a conductive layer, a light-emitting layer connected to the conductive layer, and a base layer. The plurality of pixels arranged in an array on a plane vertical to a stacking direction of the plurality of sub-pixels. The conductive layer is configured to transmit electrical signal. The light-emitting layer is configured to emit light according to the electrical signal. The base layers of the sub-pixels with a same sequence along the stacking direction are connected with each other.

### FIELD

The subject matter herein generally relates to display apparatus, and particularly relates to a display panel.

### BACKGROUND

A conventional display panel includes multiple pixels emitting light together to display images. Each of the pixels is composed by multiple sub-pixels, and each of the sub-pixels may be a red light-emitting diode (LED), a green LED, or a blue LED. For display panels of a same size, the more the pixels, the better an image quality and a color quality. Due to a coplanar arrangement of the pixels, it is difficult to reduce the size of the display panel, and manufacturing a small display panel based on the coplanar arrangement have a complex process and a low yield.

Therefore, there is room for improvement within the art.

### BRIEF DESCRIPTION OF THE DRAWINGS

Implementations of the present disclosure will now be described, by way of embodiment, with reference to the attached figures, wherein:

FIG. 1 is a schematic view of a planar structure of a display panel according to an embodiment of the present application.

FIG. 2 is a partial cross-sectional view of a display panel according to a first embodiment of the present application.

FIG. 3 is a partial cross-sectional view of a display panel according to a second embodiment of the present application.

FIG. 4 shows waveforms of pulse modulation signals from one driving circuit for driving sub-pixels of the display panel according to a first embodiment.

FIG. 5 shows waveforms of pulse modulation signals from multiple driving circuits for driving sub-pixels of the display panel according to a first embodiment.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “comprising,” when utilized, means “including, but not necessarily limited to”; it specifically indicates open-ended inclusion or membership in the so-described combination, group, series, and the like.

“Above” means one layer is on top of another layer. In one example, it means one layer is situated directly on top of another layer. In another example, it means one layer is situated over the second layer directly or indirectly with more layers or spacers in between.

When a feature or element is herein referred to as being “on” another feature or element, it can be directly on the other feature or element or intervening features and/or elements may also be present. It will also be understood that, when a feature or element is referred to as being “connected”, “attached” or “coupled” to another feature or element, it can be directly connected, attached, or coupled to the other feature or element or an intervening features or elements may be present.

### First Embodiment

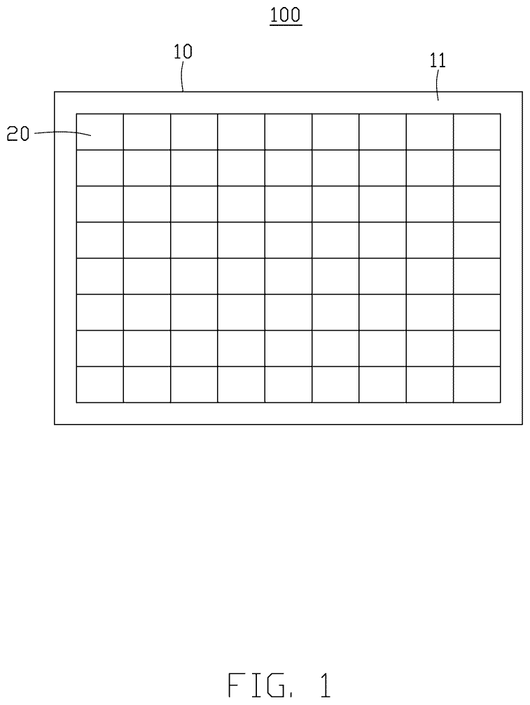

FIG. 1 shows a display panel 100 of the first embodiment includes a substrate 10 and a plurality of pixels 20 on a same surface of the substrate 10. The substrate 10 includes a driving substrate 11.

Each of the plurality of pixels 20 includes a plurality of sub-pixels 30. The plurality of sub-pixels 30 are coaxially stacked in a stacking direction parallel to a thickness direction of the plurality of sub-pixels 30. Sub-pixels 30 in a same pixel 20 are used to emit image light of different colors according to a time sequence, thereby enabling the display panel 100 to display color images. The plurality of pixels 20 are arranged in an array perpendicular to the stacking direction of the plurality of sub-pixels 30, and a size of each pixel 20 is between 1 μm˜500 μm.

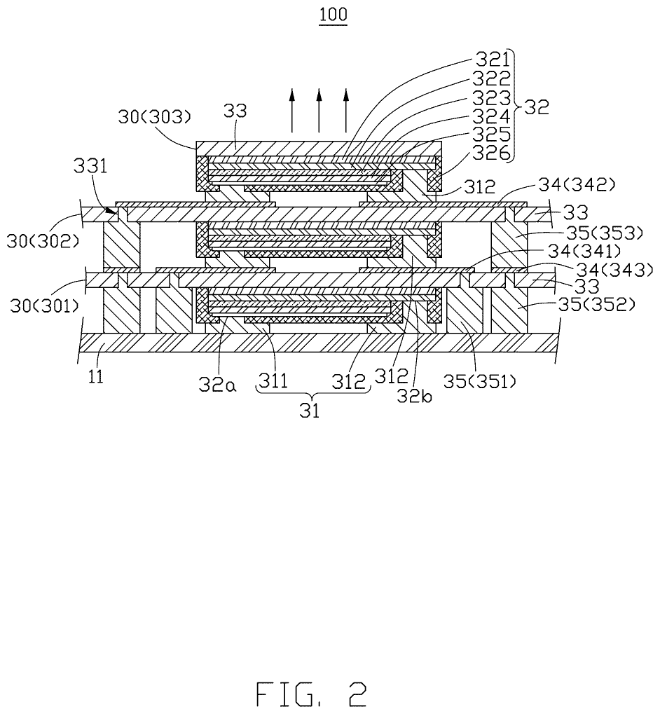

Referring to FIG. 2, each sub-pixel 30 includes a conductive layer 31, a light-emitting layer 32, and a base layer 33. The conductive layer 31 is used to transmit electrical signals. The light-emitting layer 32 is connected to the conductive layer 31 for emitting light. The base layer 33 is fixed on a side of the light-emitting layer 32 away from the conductive layer 31.

Along the stacking direction, the base layers 33 of the sub-pixels 30 with a same sequence are connected with each other. For example, the base layers 33 of the sub-pixels 30 at the top are connected to each other to form an entire layer, the base layers 33 of the sub-pixels 30 at the middle are connected to each other to form an entire layer, and the base layers 33 of the sub-pixels 30 at the bottom are connected to each other to form an entire layer. The sequence of each sub-pixel 30 indicates an order number along the stacking direction of the corresponding sub-pixel 30 in the pixel 20. The stacking direction can be from top to bottom or from bottom to top.

In this embodiment, each pixel 20 of the display panel 100 includes three sub-pixels 30, namely the first sub-pixel 301, the second sub-pixel 302, and the third sub-pixel 303, which are sequentially coaxial stacked for emitting a first light, a second light, and a third light.

Base layers 33 of all the first sub-pixels 301 are connected with each other to form an entire layer. That is, the conductive layers 31 and the light-emitting layers 32 of all the first sub-pixels 301 are on a same layer. Similarly, base layers 33 of all the second sub-pixels 302 are connected with each other to form an entire layer, and base layers 33 of all the third sub-pixels 303 are connected with each other to form an entire layer. In each pixel 20, the first sub-pixel 301 is on the driving substrate 11 of the substrate 10, the conductive layer 31 and the light-emitting layer 32 of the first sub-pixel 301 are between the base layer 33 and the driving substrate 11 of the first sub-pixel 301, the second sub-pixel 302 is on a side of the base layer 33 of the first sub-pixel 301 away from the driving substrate 11, the conductive layer 31 and the light-emitting layer 32 of the second sub-pixel 302 are between the base layer 33 of the second sub-pixel 302 and the base layer 33 of the first sub-pixel 301, the third sub-pixel 303 is on a side of the base layer 33 of the second sub-pixel 302 away from the first sub-pixel 301, and the conductive layer 31 and the light-emitting layer 32 of the third sub-pixel 303 are between the base layer 33 of the third sub-pixel 303 and the base layer 33 of the second sub-pixel 302.

In this embodiment, each sub-pixel 30 is a miniature inorganic light-emitting diode, and the light-emitting layer 32 is an inorganic light-emitting layer. In this embodiment, the light-emitting layer 32 includes a buffer layer 321, an N-type gallium nitride (GaN) layer 322, a quantum well light-emitting layer 323, a P-type GaN layer 324, a transparent conductive layer 325, and a distributed Bragg reflector (DBR) layer 326. The buffer layer 321 is on a side of the base layer 33, the N-type GaN layer 322 is on a side of the buffer layer 321 away from the base layer 33, the quantum well light-emitting layer 323 is on a side of the N-type GaN layer 322 away from the buffer layer 321, the P-type GaN layer 324 is on a side of the quantum well light-emitting layer 323 away from the N-type GaN layer 322, the transparent conductive layer 325 is on a side of the P-type GaN layer 324 away from the quantum well light-emitting layer 323, and the DBR layer 326 covers all surfaces of the light-emitting layer 32 except for a part of the surfaces contact with the base layer 33.

The buffer layer 321 includes undoped GaN used to modulate crystal structure and reduce a lattice mismatch between the base layer 33 and the N-type GaN layer 322. The N-type GaN layer 322 includes GaN doped with silicon (Si) and is used to provide electrons. The P-type GaN layer 324 is a high resistance material of GaN doped with magnesium (Mg), which is obtained after thermal annealing and is used to provide holes. The quantum well light-emitting layer 323 includes indium gallium nitride (InGaN) and GaN for emitting colored light, which can be blue, green, or red light. The transparent conductive layer 325 is used to form ohmic contact with the P-type GaN layer 324, which is beneficial for input and output of current. The DBR layer 326 is composed of a series of alternating stacked high and low refractive index materials. The DBR layer 326 can achieve high reflection of light with a certain wavelength and low reflection of light with other wavelengths by periodic refractive index changes.

In this embodiment, the DBR layer 326 of the first sub-pixel 301 is used to reflect the first light, the second light, and the third light. The DBR layer 326 of the second sub-pixel 302 is used to transmit the first light and reflect the second light and the third light. The DBR layer 326 of the third sub-pixel 303 is used to transmit the first light and the second light and reflect the third light.

In other embodiments, each sub-pixel 30 may also be an organic light-emitting diode.

The conductive layer 31 includes a first contact electrode 311 and a second contact electrode 312 on a same side of the light-emitting layer 32. The first contact electrode 311 and the second contact electrode 312 are spaced apart and on different edge parts of the light-emitting layer 32. In this embodiment, the first contact electrode 311 is on a first edge 32a of the light-emitting layer 32, and the second contact electrode 312 is on a second edge 32b of the light-emitting layer 32. The first edge 32a and second edge 32b of the light-emitting layer 32 are both etched with openings, which connects the first contact electrode 311 to the transparent conductive layer 325. The second contact electrode 312 is connected to the N-type GaN layer 322 for transmitting electrical signals to the light-emitting layer 32. The first edge 32a and the second edge 32b of the light-emitting layer 32 are both etched with openings, which connects the first contact electrode 311 to the transparent conductive layer 325. The second contact electrode 312 is connected to the N-type GaN layer 322 for transmitting electrical signals to the light-emitting layer 32. The transparent conductive layer 325 transmits the electrical signals to the P-type GaN layer 324, forming a voltage difference between the P-type GaN layer 324 and the N-type GaN layer 322, thereby driving the light-emitting layer 32 to emit light. The first contact electrode 311 and the second contact electrode 312 can be metal electrodes.

The base layer 33 is transparent and non-conductive. A material of the base layer 33 can be sapphire, silicon carbide (SiC), or Si. The base layer 33 made of sapphire can reduce a cost and increase a size of the base layer 33, so that an epitaxial layer can be heterogeneously grown on the substrate layer 33 as the light-emitting layer 32. In other embodiments, the base layer 33 may be transparent plastic if each sub-pixel 30 is an organic light-emitting diode.

Referring to FIG. 2, each pixel 20 includes a plurality of metal circuit layers 34. At least one metal circuit layer 34 is provided between the base layer 33 of the first sub-pixel 301 and the first contact electrode 311 and the second contact electrode 312 of the second sub-pixel 302, and at least one metal circuit layer 34 is between the base layer 33 of the second sub-pixel 302 and the first contact electrode 311 and the second contact electrode 312 of the third sub-pixel 303. Each metal circuit layer 34 is on a side of the base layer 33 away from the substrate 11. Each metal circuit layer 34 connects the conductive layer 31 of one adjacent sub-pixel 30. The base layer 33 of each sub-pixel 30 (except for the third sub-pixel 303) contacts with at least one metal circuit layer 34. The base layers 33 of the first sub-pixels and the second sub-pixels are formed with a plurality of through holes 331 in an area which is not in contact with the light-emitting layers 32. Pulse conducting electrodes 35 are formed on a side of each base layer 33 away from the metal circuit layer 34, and the pulse conducting electrodes 35 extend through the through holes 331 to connect the metal circuit layers 34.

In this embodiment, each pixel 20 includes three metal circuit layers 34, namely a first metal circuit layer 341, a second metal circuit layer 342, and a third metal circuit layer 343. The first metal circuit layer 341 is on a side of the base layer 33 of the first sub-pixel 301 away from the light-emitting layer 32. The first metal circuit layer 341 is connected to the first contact electrode 311 and the second contact electrode 312 of the second sub-pixel 302. The second metal circuit layer 342 is on a side of the base layer 33 of the second sub-pixel 302 away from the light-emitting layer 32. The second metal circuit layer 342 is connected to the first contact electrode 311 and the second contact electrode 312 of the third sub-pixel 302. The third metal circuit layer 343 is on a side of the base layer 33 of the first sub-pixel 301 away from the light-emitting layer 32. The third metal circuit layer 343 is connected to the second sub-pixel 302.

The pulse conducting electrodes 35 includes a first pulse conducting electrode 351, a second pulse conducting electrode 352, and a third pulse conducting electrode 353. The first pulse conducting electrode 351 is on a side of the base layer 33 of the first sub-pixel 301 away from the first metal circuit layer 341. The first pulse conducting electrode 351 is connected to the first metal circuit layer 341 through one through hole 331. The second pulse conduction electrode 352 is on a side of the base layer 33 of the first sub-pixel 301 away from the third metal circuit layer 343. The second pulse conduction electrode 352 is connected to the third pulse conducting electrode 353 through one through hole 331. The third pulse conducting electrode 353 is between the base layer 33 and the third metal circuit layer 343 of the second sub-pixel 302. The third pulse conducting electrode 353 is connected to the third metal circuit layer 343 and the second metal circuit layer 342 by extending through the through hole 331.

The driving substrate 11 of the substrate 10 is on a side of the conductive layer 31 of the first sub-pixel 301 away from the light-emitting layer 32. The driving substrate 11 is connected to the first contact electrode 311 and the second contact electrode 312 of the first sub-pixel 301. The driving substrate 11 is used to transmit electrical signals to the first sub-pixel 301 to emit the first light. The driving substrate 11 connects the first contact electrode 311 and the second contact electrode 312 of the second sub-pixel 302 through the first pulse conducting electrode 351 and the first metal circuit layer 341. The driving substrate 11 is used to transmit the electrical signals to the second sub-pixel 302 to emit the second light. The driving substrate 11 connects the first contact electrode 311 and the second contact electrode 312 of the third sub-pixel 303 through the second pulse conducting electrode 352, the third metal circuit layer 343, the third pulse conducting electrode 353, and the second metal circuit layer 342. The driving substrate 11 is used to transmit the electrical signals to the third sub-pixel 303 to emit the third light.

In this embodiment, the first sub-pixel 301, the second sub-pixel 302, and the third sub-pixel 303 have a same size on the plane vertical to the stacking direction. Along the stacking direction, the first light propagates upwards (towards human eyes) and passes through the base layer 33 of the first sub-pixel 301, the second sub-pixel 302, and the third sub-pixel 303. The second light propagates upwards (towards human eyes) and passes through the base layer 33 of the second sub-pixel 302 and the third sub-pixel 303. The third light propagates upwards (towards human eyes) and passes through the base layer 33 of the third sub-pixel 303. The first light, the second light, and the third light are in different colors and are received by human eyes to show images to users.

In this embodiment, the first light is blue light, the second light is green light, and the third light is red light. In other embodiments, the first light, the second light, and the third light can be interchanged. For example, in other embodiments, the first light is red light, the second light is green light, and the third light is blue light, or the first light is green light, the second light is blue light, and the third light is red light.

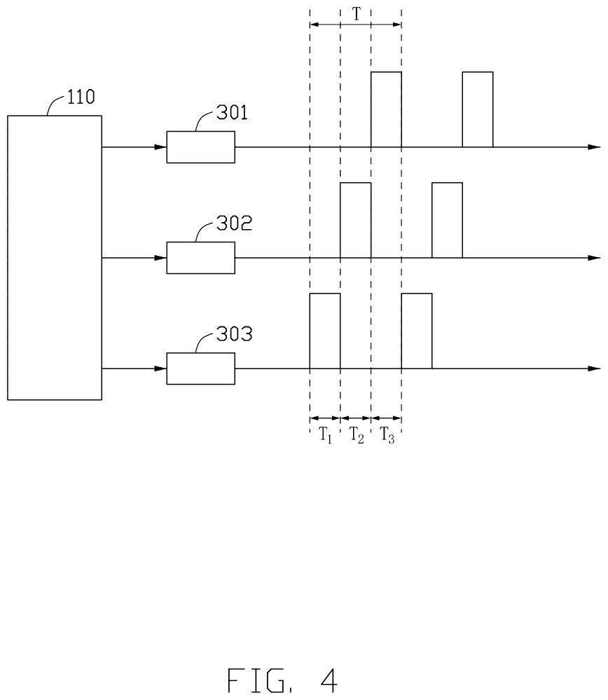

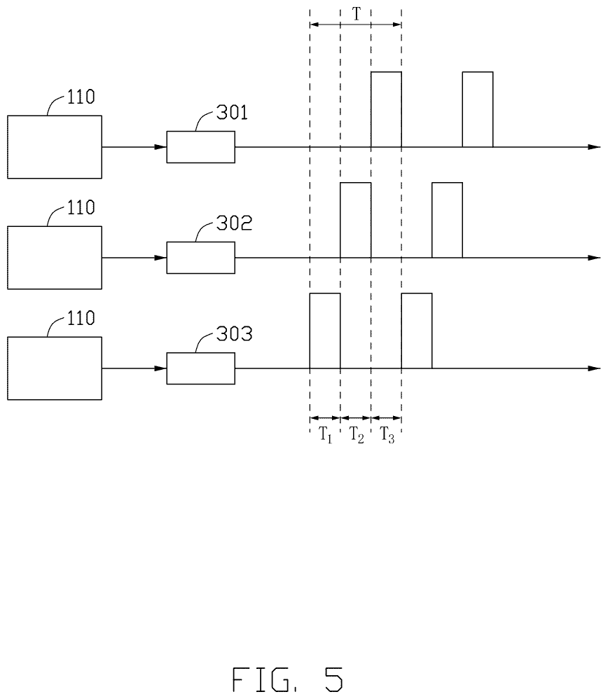

The driving substrate 11 includes a driving circuit 110 (see FIG. 4). The driving circuit 110 is used to control emission periods of the sub-pixels 30 through pulse modulation, so that different sub-pixels 30 in a same pixel 20 receive the electrical signals at different periods to emit light at different periods. The driving substrate 11 can include one driving circuit 110 to control the sub-pixels 30 simultaneously (see FIG. 4), or the driving substrate 11 can include a plurality of driving circuits 110 to control the sub-pixels 30, respectively (see FIG. 5).

A driving pulse period T of the driving circuit 110 includes three periods, namely a first period T1, a second period T2, and a third period T3. The driving circuit 110 drives the first sub-pixel 301 to emit the first light during the first period T1, drives the second sub-pixel 302 to emit the second light during the second period T2, and drives the third sub-pixel 303 to emit the third light during the third period T3. That is, during the driving pulse period T, the driving circuit 110 sequentially drives the first sub-pixel 301, the second sub-pixel 302, and the third sub-pixel 303 to emit light, causing the three sub-pixels 30 in a same pixel 20 to emit different colors of light during different periods. Based on a visual persistence principle, the human eyes can receive image light mixed with three colors of light (the first light, the second light, and the third light) if a frequency of the driving pulse is greater than 120 Hz.

Each pixel 20 of the display panel 100 in this embodiment is composed of three sub-pixels 30. The first sub-pixel 301, the second sub-pixel 302, and the third sub-pixel 303 are sequentially connected through coaxial stacking, so that the first sub-pixel 301, the second sub-pixel 302, and the third sub-pixel 303 are on different planes, which is conducive to reducing a volume of each pixel 20, facilitating the display panel 100 applying on small devices such as AR glasses, and enhancing user experience.

### Second Embodiment

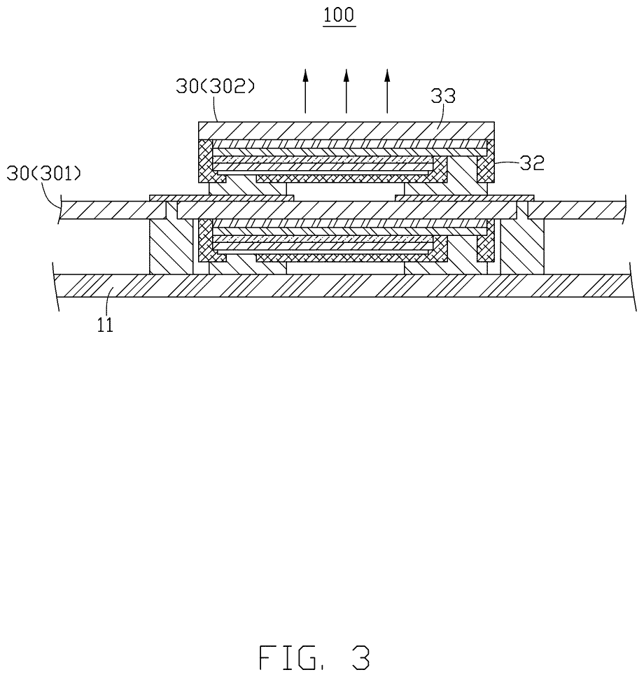

Referring to FIG. 3, different from the first embodiment, each pixel 20 of the display panel 100 in this embodiment includes two sub-pixels 30 (i.e., the first sub-pixel 301 and the second sub-pixel 302). The first sub-pixel 301 and the second sub-pixel 302 are coaxially stacked along the thickness direction. The first sub-pixel 301, the second sub-pixel 302, and the driving substrate 11 connect as the same with the first embodiment, and the driving substrate 11 drives the first sub-pixel 301 and the second sub-pixel 302 in the same way as described in the first embodiment.

Along the stacking direction, the first light emitted by the first sub-pixel 301 propagates upwards (towards the human eye) and passes through the base layer 33 of the first sub-pixel 301 and the second sub-pixel 302. The second light emitted by the second sub-pixel 302 propagates upwards (towards the human eye) and passes through the base layer 33 of the second sub-pixel 302. The first light and the second light are in different colors and are received by the human eyes to show images to the users. In this embodiment, the first light is green light, and the second light is red light. In other embodiments, the first light may be red light, and the second light may be green light.

Each pixel 20 in this embodiment includes two sub-pixels 30 to display images, which

has low energy consumption, longer service life, as well as high luminous efficiency, and can achieve high brightness display effects.

In summary, the embodiments of this application have the following beneficial effects:

In the display panels 100 above, all sub-pixels 30 in a same pixel 20 are coaxially stacked along the stacking direction (i.e. the thickness direction). In each pixel 20, the sub-pixel 30 at the bottom (i.e. the first sub-pixel 301 in the first embodiment and the second embodiment) connects the driving substrate 11, the remaining sub-pixels 30 connect the driving substrate 11 through the pulse conducting electrodes 35 and the metal circuit layers 34. Sub-pixels 30 in a same pixel 20 connect the driving substrate 11 respectively, so that the driving substrate 11 can transmits electrical signals to the sub-pixels 30 respectively. The driving circuit 110 of the driving substrate 11 controls the emission periods of the sub-pixels 30 in a same pixel 20 through pulse modulation, so that the sub-pixels 30 in a same pixel 20 receives the electrical signals and emit lights during different periods. Based on the visual persistence principle, the human eye can recognize the image light mixed with multiple colors of light when the pulse frequency of the pulse modulation is greater than a recognition frequency of the human eye. Compared to display panels in the art, the sub-pixels 30 in each pixel 20 of the display panel 100 of the present disclosure are not on a same plane and are stacked coaxially, which is conducive to reducing the volume of each pixels 20 of the display panel 100, simplifying a production process of the display panels 100, and increasing the producing yield.

Finally, it should be noted that the above embodiments are only used to illustrate the technical solution of the present application and not to limit the present application. Although the present application has been described in detail with reference to preferred embodiments, one ordinary skill in the art should understand that the technical solution of the present application can be modified or equivalent replaced without departing from the spirit and scope of the technical solution of the present application.

What is claimed is:

1. A display panel comprising:
a substrate; and
a plurality of pixels on the substrate, each of the plurality of pixels comprising a plurality of sub-pixels coaxially stacked, each of the plurality of sub-pixels comprising a conductive layer, a light-emitting layer electrically connected to the conductive layer, and a base layer, the plurality of pixels arranging in an array on a plane vertical to a stacking direction of the plurality of sub-pixels;
wherein the conductive layer is configured to transmit an electrical signal, the light-emitting layer is configured to emit light in response to the electrical signal, and the plurality of sub-pixels is stacked in a sequence, along the stacking direction, the base layers of the sub-pixels with a same sequence are connected with each other.

2. The display panel according to claim 1, wherein the conductive layer comprises a first conducting electrode and a second conducting electrode on a same side of the light-emitting layer, and the base layer contacts a side of the light-emitting layer away from the conductive layer; and
each of the plurality of pixels comprises a plurality of metal circuit layers on a side of the base layer away from the light-emitting layer, the plurality of metal circuit layers connect the conductive layer of an adjacent pixel, a part of the base layer contact at least one of the plurality of metal circuit layers and not contact the light-emitting layer is formed with a plurality of through holes, at least one pulse conducting electrode is on a side of the base layer away from the plurality of metal circuit layers, and the at least one pulse conducting electrode connects to at least one of the plurality of metal circuit layers through at least one of the plurality of through holes.

3. The display panel according to claim 2, wherein the substrate comprises a driving substrate;
the driving substrate is at a side of the conductive layer of the sub-pixel at the bottom away from the light-emitting layer; and
the driving substrate connects the conductive layer and is configured to send electrical signals to the plurality of sub-pixels to drive the plurality of sub-pixels to emit light.

4. The display panel according to claim 3, wherein the driving substrate connects at least one of the plurality of pulse conducting electrodes, each of the plurality of pulse conducting electrode is configured to send the electrical signal to the plurality of sub-pixels in each of the plurality of pixels except for a bottommost sub-pixel.

5. The display panel according to claim 4, wherein the driving substrate is configured to control the plurality of sub-pixels to emit light during different periods by pulse modulation.

6. The display panel according to claim 5, wherein the driving substrate comprises one driving circuit to control the plurality of sub-pixels.

7. The display panel according to claim 5, wherein the driving substrate comprises a plurality of driving circuits to control the plurality of sub-pixels.

8. The display panel according to claim 1, wherein the plurality of sub-pixels in each of the plurality of pixels emit light of different colors.

9. The display panel according to claim 8, wherein the light-emitting layer is configured to emit red light, green light, or blue light according to the electrical signal.

10. The display panel according to claim 1, wherein the light from the light-emitting layer transmits along the stacking direction away from the substrate.

11. The display panel according to claim 1, wherein the base layer of the sub-pixel at the top covers the light-emitting layer of the sub-pixel at the top.

12. The display panel according to claim 1, wherein each of the plurality of pixels comprises a first sub-pixel and a second sub-pixel coaxially stacked along the stacking direction; and
the base layers of the first sub-pixels of the plurality of pixels are connected with each other, and the base layers of the second sub-pixels of the plurality of pixels are connected with each other.

13. The display panel according to claim 12, wherein each of the plurality of pixels further comprises a third sub-pixel on a side of the second sub-pixel away from the first sub-pixel, the first sub-pixel, the second sub-pixel, and the third sub-pixel are coaxially stacked along the stacking direction; and
the base layers of the third sub-pixels of the plurality of pixels are connected with each other.

14. The display panel according to claim 12, wherein the first sub-pixel is configured to emit red light, and the second sub-pixel is configured to emit green light; or
the first sub-pixel is configured to emit green light, and the second sub-pixel is configured to emit red light.

15. The display panel according to claim 12, wherein the first sub-pixel is configured to emit a first light, and the second sub-pixel is configured to emit a second light; and
the first light passes through the second sub-pixel to show an image.

16. The display panel according to claim 12, wherein the first light is red light and the second light is green light; or
The first light is green light and the second light is red light.

17. The display panel according to claim 1, wherein the plurality of sub-pixels have a same size on the plane vertical to the stacking direction.

18. A display panel comprising:
a substrate; and
a plurality of pixels on the substrate, each of the plurality of pixels comprising a plurality of sub-pixels coaxially stacked, each of the plurality of sub-pixels comprising a conductive layer, a base layer and a light-emitting layer connected between the conductive layer and the base layer, the plurality of pixels arranging in an array on a plane vertical to a stacking direction of the plurality of sub-pixels;
wherein the conductive layer is configured to transmit an electrical signal, the light-emitting layer is configured to emit light according to the electrical signal, and the plurality of sub-pixels have a same size on the plane vertical to the stacking direction.
